(19) United States
(12) Patent Application Publication
(10) Pub. No.: US 2003/0011360 A1
(43) Pub. Date: Jan. 16, 2003

(54) Magnetoresistive angle sensor

(76) Inventors: Heiko Jausel, Neustadt an (DE); Wolfgang Porth, Frankfurt (DE)

Correspondence Address: Martin A. Farber, Suite 473, 866 United Nations Plaza, New York, NY, 10017, US

(21) Appl. No.: 10/167,236

(22) Filed: Jun. 10, 2002

(30) Foreign Application Priority Data
Jul. 13, 2001 (JP) 101 33 559.8

(51) Int. Cl. G01B 7/30; G01R 33/09

(52) U.S. Cl. 324/207.21; 324/207.25

(57) ABSTRACT

A magnetoresistive angle sensor for use in areas with temperatures in excess of 160° C. has a fixed magnetic field sensor (2, 3), which is surrounded by a permanently magnetic rotor (8) and a shielding ring (9) rotating with the latter. The magnetic field sensor (2, 3) is designed for determining the angular position of this rotor (8). The rotor (8) forms a ring, surrounding the magnetic field sensor (2, 3), of a plastic with rare-earth magnetic material incorporated in it, which material is a compound of neodymium, iron and boron.

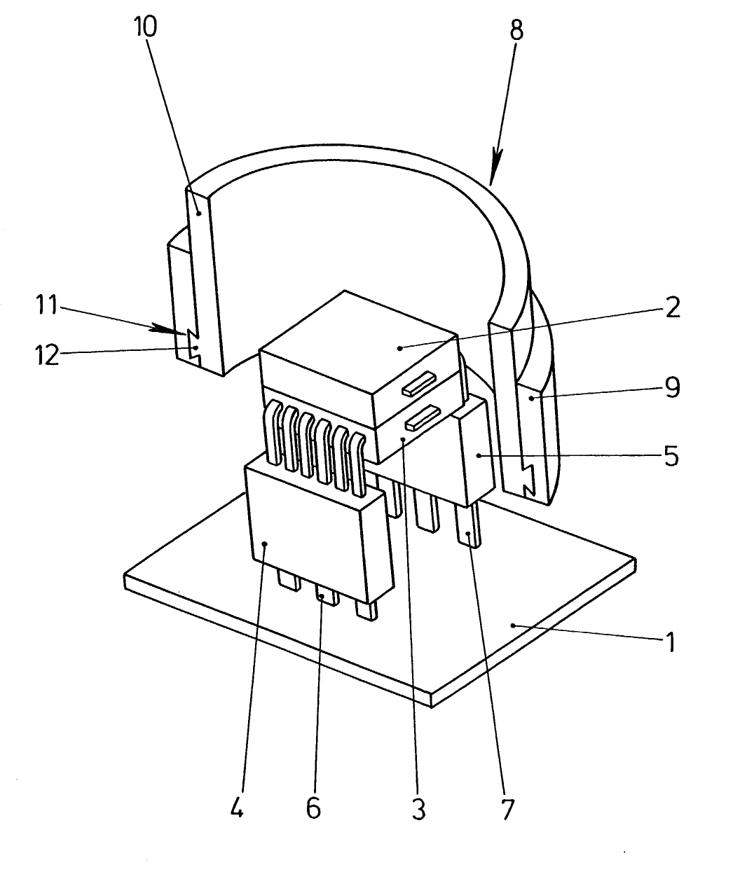

The invention relates to a magnetoresistive angle sensor for use in areas with temperatures in excess of 160° C., in which a fixed magnetic field sensor is surrounded by a permanently magnetic rotor and a shielding ring rotating with the latter, the magnetic field sensor serving for determining the angular position of this rotor.

Angle sensors of the aforementioned type are used for example in motor vehicles for determining the throttle valve position or for the variable valve control of an internal combustion engine within the internal combustion engine for monitoring the camshaft position. Such angle sensors require magnets which generate a magnetic field which is homogeneous with respect to the field direction and as strong as possible and which rotates in relation to the magnetic field sensor. The relative change in field direction is then detected by the magnetic field sensor.

In the case of the current angle sensors of the aforementioned type, individual annular or cuboidal magnets of rare-earth magnetic material are inserted in a carrier. In this case, circularity and positional tolerances lead to problems. Since rare-earth magnets are very brittle, it is even common for the magnets to break during the production of the angle sensors, requiring the entire sensor system to be rejected. In the case of sintered magnets, a noticeable disadvantage for use as an angle sensor is that they are inhomogeneous with respect to the field strength and field direction on account of their method of production. Furthermore, sintered magnets of rare-earth magnetic material NdFeB (neodymium, iron and boron) are very susceptible to corrosion, so that additional corrosion protection is necessary for use in motor vehicles. If the angle sensor has to operate at temperatures in excess of 160° C. and field strengths in excess of 50 kA/m are necessary along with the required small overall size, it has currently been necessary to resort to the expensive rare-earth magnetic material SmCo.

The invention is based on the problem of designing an angle sensor of the type stated at the beginning in such a way that it can withstand temperatures in excess of 160° C., has only small circularity tolerances and generates a very homogeneous field.

This problem is solved according to the invention by the rotor being formed as a ring of a plastic with rare-earth magnetic material incorporated in it.

The incorporation of the rare-earth magnetic material in the material of a ring of plastic produces a very homogeneous magnetic field with respect to the strength and field directions. At the same time, incorporation in the plastic ensures that the magnetic material is protected from corrosion and prevents problems in respect of circularity and consequently unbalance. At the same time, the plastic protects the magnetic material from temperature effects, so that the angle sensor can be exposed to higher temperatures than an angle sensor with individually inserted magnets.

The magnetoresistive angle sensor can be produced at particularly low cost if, according to a development of the invention, the rare-earth magnetic material is a compound of neodymium, iron and boron.

Since the plastic likewise has to withstand relatively high temperatures, it is favorable if the plastic incorporating the rare-earth magnetic material is a plastic that is resistant to high temperatures. As tests have shown—advantageously suitable for this in the case of the magnetoresistive angle sensor for use in areas with temperatures in excess of 160° C. is polyphenylene sulfide (PPS) or a liquid-crystal polymer (LCP).

The magnetoresistive angle sensor can be produced at particularly low cost if the rotor is molded directly onto the inside of the shielding ring by the injection-molding process. Practice has shown that the thickness of the shielding ring can be chosen such that the rotor can be magnetized through the shielding ring within the injection mold, so that there is no longer any need for advance handling of a strong magnet.

The rotor is held particularly reliably within the shielding ring if, according to another development of the invention, the shielding ring has in its inner lateral surface back-molded formations for producing a form fit with the molded-on rotor.

The mounting of the rotor with the shielding ring can take place in a simple way over a partial region of the rotor if a magnet holder is molded onto one side of the assembly comprising the rotor and the shielding ring. The holder may be formed, for example, as a shaft.

To illustrate the invention further, a magnetoresistive angle sensor according to the invention is schematically represented in the drawing and is described below.

The drawing perspectively shows a fixedly arranged printed circuit board 1 (for example of flexible material or standard printed circuit board material or having a lead frame), on which two magnetic field sensors 2, 3 and two evaluation units 4, 5 are arranged. The two evaluation units 4, 5 have output terminals 6, 7, which are electrically connected to the printed circuit board 1.

The magnetic field sensors 2, 3 are enclosed by a rotor 8 of magnetic material, on the outside of which a shielding ring 9 of a material conducting the magnetic flux, in particular soft iron, is arranged. The rotor 8 protrudes beyond the shielding ring 9 with a magnet holder 10, which serves for mounting the unit comprising the rotor 8 and the shielding ring 9. The shielding ring 9 has on its inner lateral surface a set-back, undercut recess 11, which is filled by a back-molded formation 12 of the rotor material.

It is important for the invention that the rotor 8 is formed from a plastic with rare-earth magnetic material incorporated in it. The rare-earth magnetic material is preferably a compound of neodymium, iron and boron. The plastic incorporating this material is, for example, a polyphenylene sulfide (PPS). The plastic-bonded rare-earth magnetic material is injection-molded directly into the shielding ring 9.

1. A magnetoresistive angle sensor for use in areas with temperatures in excess of 160° C., in which a fixed magnetic field sensor is surrounded by a permanently magnetic rotor and a shielding ring rotating with the latter, the magnetic field sensor serving for determining the angular position of this rotor, characterized in that the rotor (8) is formed as a ring of a plastic with rare-earth magnetic material incorporated in it.

2. The magnetoresistive angle sensor as claimed in claim 1, characterized in that the rare-earth magnetic material is a compound of neodymium, iron and boron.

3. The magnetoresistive angle sensor as claimed in claim 1 or 2, characterized in that the plastic incorporating the rare-earth magnetic material is polyphenylene sulfide (PPS) or a liquid-crystal polymer (LCP).

4. The magnetoresistive angle sensor as claimed in at least one of the preceding claims, characterized in that the rotor (8) is molded directly onto the inside of the shielding ring (9) by the injection-molding process.

5. The magnetoresistive angle sensor as claimed in claim 4, characterized in that the shielding ring (9) has in its inner lateral surface back-molded formations for producing a form fit with the molded-on rotor (8).

6. The magnetoresistive angle sensor as claimed in at least one of the preceding claims, characterized in that a magnet holder (10) is molded onto one side of the assembly comprising the rotor (8) and the shielding ring (9).
